(19) United States
(12) Patent Application Publication
(10) Pub. No.: US 2026/0182191 A1
(43) Pub. Date: Jun. 25, 2026

(54) DISPLAY PANEL AND DISPLAY DEVICE

(71) Applicant: Wuhan Tianma Microelectronics Co., Ltd., Wuhan (CN)

(72) Inventors: Qiyuan ZHOU, Wuhan (CN); You GAO, Wuhan (CN)

(73) Assignee: Wuhan Tianma Microelectronics Co., Ltd., Wuhan (CN)

(21) Appl. No.: 19/380,914

(22) Filed: Nov. 5, 2025

(30) Foreign Application Priority Data
Dec. 25, 2024 (CN) 202411932423.7

(51) Int. Cl. H10K 59/131; H10H 20/819; H10H 29/49; H10K 59/88; H10K 77/10

(52) U.S. Cl. CPC H10K 59/1315; H10H 20/819; H10H 29/49; H10K 59/88; H10K 77/111

(57) ABSTRACT

The present application discloses a display panel and a display device, the display panel comprises a display and non-display area, a substrate and a power supply structure located on a side of the substrate, the power supply structure is located in the non-display area and located on a side of the display area in a first direction and comprises a first and a second section, a wire-entry end, and a connection portion, the first section, the connection portion, the second section, and the wire-entry end are sequentially arranged away from the display area in the first direction. The connection portion extends in the first direction, the first section and the second section extend in a second direction intersecting with the first direction, the connection portion is connected to the first and second section, the wire-entry end is connected to the second section.

### CROSS-REFERENCE TO RELATED APPLICATION

The present application claims priority to Chinese Patent Application No. 202411932423.7 filed on Dec. 25, 2024, and titled “DISPLAY PANEL AND DISPLAY DEVICE”, which is incorporated herein by reference in its entirety.

### TECHNICAL FIELD

The present application relates to the technical field of displays, and particularly relates to a display panel and a display device.

### BACKGROUND

With the development of display technology, display devices specially designed for automobiles have become an important kind of display product. At present, the display area of vehicle-mounted display products is large. To improve the visual effect, it is necessary to compress the bezel of the display product. However, under the design requirements of a narrow bezel, there is a problem that the display at the power inlet port is bright, which leads to uneven display.

### SUMMARY

Embodiments of the present application provide a display panel and a display device to solve the technical problem that how to improve display uniformity.

In a first aspect, embodiments of the present application provide display panel, comprising a display area and a non-display area, the display panel comprises a substrate and a power supply structure located on a side of the substrate, the power supply structure is located in the non-display area and located on a side of the display area in a first direction; the power supply structure comprises a first section, a second section, a wire-entry end, and a connection portion, the first section, the connection portion, the second section, and the wire-entry end are sequentially arranged away from the display area in the first direction; the connection portion extends in the first direction, the first section and the second section extend in a second direction intersecting with the first direction, the connection portion is connected to the first section and the second section, and the wire-entry end is connected to the second section; and the substrate is provided with a bending region located between the first section and the second section in the first direction, and at least part of the connection portion is located in the bending region.

In a second aspect, based on the same inventive concept, embodiments of the present application provide a display device, comprising: the display panel according to any one of the embodiments.

The embodiments of the present application provide a display panel and a display device which have the following beneficial effects. In the power supply structure located in the non-display area in an embodiment of the present application, the first section is close to the display area, the wire-entry end is away from the display area, and the connection portion is connected between the first section and the second section, and the power supply signal is introduced into the second section by the wire-entry end. The connection portion is provided in the bending region, and when the bending region is in the bent state, the second section and the wire-entry end can be placed on the back surface of the display panel, so that a narrow bezel of the display panel can be achieved. Moreover, since the second section is finally placed on the back surface of the display panel, the width of the second section in the first direction is not limited, whereby the distance from the source of the power supply signal to the display area can be increased, so that the power supply signal is uniformly transmitted in the second section first, and the difference in the voltage drop of the power supply signal in the second direction can be balanced. Then, the power supply signal is introduced into the first section by the connection portion, and the power supply signal is introduced into the display area by the first section, so that the problem of localized brightness of a side of the display area close to the power supply structure can be ameliorated, and the display uniformity can be improved.

### BRIEF DESCRIPTION OF THE DRAWINGS

In order to more clearly explain the embodiments of the present application or the technical solutions in the prior art, the drawings that need to be used in the description of the embodiments or the prior art will be briefly introduced below, and it is obvious that the drawings in the following description are some embodiments of the present application, and for those skilled in the art, other drawings can be obtained according to these drawings without making creative labor.

FIG. 1 is a schematic diagram of a display panel according to the related art;

FIG. 2 is a schematic diagram of a display panel according to an embodiment of the present application;

FIG. 3 is a schematic diagram of a display panel provided by another embodiment of the present application;

FIG. 4 is a schematic diagram of a display panel provided by yet another embodiment of the present application;

FIG. 5 is a schematic diagram of a display panel provided by yet another embodiment of the present application;

FIG. 6 is a schematic diagram of a display panel provided by yet another embodiment of the present application;

FIG. 7 is a schematic diagram of a display panel provided by yet another embodiment of the present application;

FIG. 8 is a partial schematic view of a display panel provided by yet another embodiment of the present application;

FIG. 9 is a schematic cross-sectional view at line A-A′ in FIG. 2; and

FIG. 10 is a schematic diagram of a display device according to an embodiment of the present application.

### DETAILED DESCRIPTION

In order to make the objects, technical solutions, and advantages of embodiments of the present application more clear, the technical solutions in the embodiments of the present application will be clearly and completely described below with reference to the drawings in the embodiments of the present application, and it is obvious that the described embodiments are part of the embodiments of the present application, but not all the embodiments. Based on the embodiments in the present application, all other embodiments obtained by those skilled in the art without creative work fall within the scope of protection of the present application.

The terminology used in the embodiments of the present application is for the purpose of describing particular embodiments only and is not intended to limit the present application. As used in the embodiments of the present application and the appended claims, the singular forms “a,” “the,” and “said” are also intended to include the plurality of forms unless the context clearly indicates otherwise.

It should be understood that although the terms first and second may be employed to describe XX in embodiments of the present application, these XX should not be limited to these terms. These terms are used only to distinguish XX from each other. For example, the first XX may also be referred to as the second XX, and similarly, the second XX may also be referred to as the first XX without departing from the scope of the embodiments of the present application.

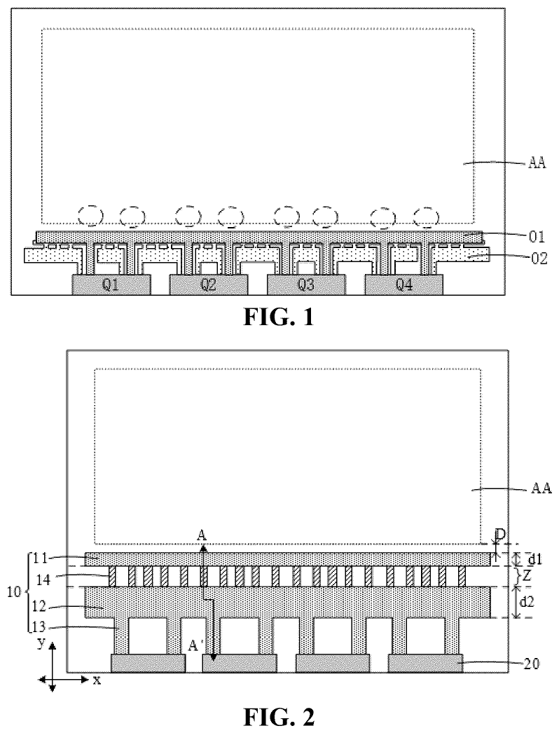

FIG. 1 is a schematic diagram of a display panel of the related art, which schematically illustrates a medium-sized product currently used in vehicle-mounted applications, and the display screen size is about 12-30 inches. As shown in FIG. 1, since the display panel is large in size, a multi-COF (Chip-On-Flex) method is used for driving. FIG. 1 shows the binding regions corresponding to four COFs, which are Q1, Q2, Q3, and Q4 respectively. FIG. 1 also schematically illustrates the wiring of the positive electrode power supply structure 01 and the negative electrode power supply structure 02 required for driving the display panel to display in the non-display area. In the related art, a region (a region circled by a dotted line in FIG. 1) corresponding to the wire-entry port of the positive electrode power supply structure 01 in the display area AA has a brightness problem, and a local position of the display area AA close to the positive electrode power supply structure 01 becomes excessively bright, resulting in overall uneven brightness of the display panel.

The inventors consider that since the display area of the medium-sized product is larger, the overall current on the positive electrode power supply structure 01 is larger, and the current path of the positive electrode power supply signal in the display area AA is longer, the voltage drop of the overall positive electrode power supply signal is large, which can easily cause uneven brightness. In addition, in order to achieve the effect of a narrow bezel, compression of the lower bezel leads to a closer distance from the wire-entry port to the display area AA, which results in a higher brightness of the display area corresponding to the wire-entry port.

In order to solve the problems existing in the related art, embodiments of the present application provide a display panel, which improves the wire-entry layout of a power supply structure in a non-display area to improve the current uniformity of a wire-entry region of the power supply structure, optimize the problem of higher brightness of a display area corresponding to a wire-entry port caused by a voltage drop of a power supply signal, and improve display uniformity.

FIG. 2 is a schematic diagram of a display panel according to an embodiment of the present application. As shown in FIG. 2, the display panel includes a display area AA and a non-display area NA. The display panel includes a substrate (not shown in FIG. 2) and a power supply structure 10 located in a side of the substrate. The power supply structure 10 is located on the non-display area NA and on a side of the display area AA in the first direction y. The display area AA includes a light-emitting device, which may be an organic light-emitting device or an inorganic light-emitting device. The display panel further includes a pixel circuit, wherein a cathode of the light-emitting device receives a negative electrode power supply signal, an anode is connected to the pixel circuit, and one port of the pixel circuit receives a positive electrode power supply signal. Optionally, the power supply structure 10 is a positive electrode power supply structure that is configured to provide a positive electrode power supply signal.

As shown in FIG. 2, the power supply structure 10 includes a first section 11, a second section 12, a wire-entry end 13, and a connection portion 14. In the first direction y away from the display area AA, the first section 11, the connection portion 14, the second section 12, and the wire-entry end 13 are sequentially arranged. The connection portion 14 extends in the first direction y, the first section 11 and the second section 12 extend in a second direction x intersecting with the first direction y, the connection portion 14 is connected to the first section 11 and the second section 12, and the wire-entry end 13 is connected to the second section 12. The substrate in the display panel is provided with a bending region Z. In the first direction y, the bending region Z is located between the first section 11 and the second section 12, and at least part of the connection portion 14 is located in the bending region Z.

In the power supply structure 10 located in the non-display area NA in an embodiment of the present application, the first section 11 is close to the display area AA, the wire-entry end 13 is away from the display area AA, and the connection portion 14 is connected between the first section 11 and the second section 12, and the power supply signal is introduced into the second section 12 by the wire-entry end 13. The connection portion 14 is provided in the bending region Z, and when the bending region Z is in the bent state, the second section 12 and the wire-entry end 13 can be placed on the back surface of the display panel, so that a narrow bezel of the display panel can be achieved. Moreover, since the second section 12 is finally placed on the back surface of the display panel, the width of the second section 12 in the first direction y is not limited, whereby the distance from the source of the power supply signal to the display area AA can be increased, so that the power supply signal is uniformly transmitted in the second section 12 first, and the difference in the voltage drop of the power supply signal in the second direction x can be balanced. Then, the power supply signal is introduced into the first section 11 by the connection portion 14, and the power supply signal is introduced into the display area AA by the first section 11, so that the problem of localized brightness of a side of the display area close to the power supply structure 10 can be ameliorated, and the display uniformity can be improved.

In some embodiments, as shown in FIG. 2, in the first direction y, the width of the first section 11 is d1, and the width of the second section 12 is d2. The width d2 of the second section 12 is greater than the width d1 of the first section 11. In an embodiment of the present application, if a bending region Z is provided between the first section 11 and the second section 12, and when the bending region Z is in a bent state, the second section 12 and the wire-entry end 13 can be placed on the back surface of the display panel, the width d1 of the first section 11 affects the size of the bezel of the display panel, and the width of the second section 12 in the first direction y is not limited. By setting d2 to be greater than d1, the width d2 of the second section 12 can be set to be sufficiently great to increase the distance from the source of the power supply signal to the display area AA, so that the power supply signal is uniformly transmitted in the second section 12 first; by setting the width d1 of the first section 11 to be small, it is possible to facilitate the realization of a narrow bezel of the display panel.

In some embodiments, in the first direction y, the width of the first section 11 is d1 and the width of the second section 12 is d2, where 0.25≤d1:d2≤0.5. In this embodiment, by setting a certain proportional range between d1 and d2, it is possible to prevent the width d2 of the second section 12 from being too great and affecting power consumption, and it is possible to prevent the width d1 of the first section 11 from being too small and affecting the effect of balancing the difference in voltage drop of the power supply signal.

In some embodiments, the width of the second section 12 in the first direction y is d2, where d2≥500 μm. When the bending region Z is in the bent state, the second section 12 and the wire-entry end 13 can be placed on the back surface of the display panel, and the width of the second section 12 in the first direction y is not limited. In an embodiment of the present application, d2 is set to satisfy a certain range, ensuring that the width d2 of the second section 12 is relatively great, which can increase the distance from the source of the power supply signal to the display area AA, enable the power supply signal to be uniformly transmitted in the second section 12 first, and enable the difference in voltage drop of the power supply signal in the second direction x to be balanced, thereby ameliorating the problem of localized brightness on the side of the display area AA close the side of the power supply structure 10, and improving the display uniformity.

As shown in FIG. 2, in the first direction y, the distance from the first section 11 to the display area AA is D, where 100 μm≤D≤500 μm. The display area AA is a light-emitting area on the panel, and the boundary between the display area AA and the non-display area NA is defined by the edge of the pixel circuit in the display area AA. The range of D is limited in an embodiment of the present application. The value of D is not too small, and the structures made of the same layer of materials in the display area AA of the first section 11 can be ensured to be insulated from each other and short circuit can be avoided; the value of D is not too great, and it is possible to ensure that the display panel has a lower bezel with a small size.

In some embodiments, the width of the connection portion 14 in the second direction x is not less than 300 μm. This arrangement reduces the resistance of the connection portion 14 and reduces the voltage drop of the transmission of the power supply signal on the connection portion 14.

In some embodiments, as shown in FIG. 2, the connection portion 14 and the wire-entry end 13 are at least partially non-overlapping in the first direction y. In other words, the connection portion 14 and the wire-entry end 13 are not located on the same straight line extending in the first direction y. Such an arrangement can avoid excessive concentration of current when it is transmitted to the display area AA along the first direction y, which is beneficial to improving current uniformity in the wire-entry area of the power supply structure 10 and optimizes the problem of the display area corresponding to the wire-entry port brightening due to the voltage drop of the power supply signal.

In some embodiments, as shown in FIG. 2, the display panel includes n pad groups 20, where n is an integer, and n≥2. FIG. 2 takes n=4 as an example, which indicates the position of the pad groups 20 and does not illustrate the plurality of pads included in the pad group 20. It can be understood that a plurality of pads are arranged in the second direction x within the pad group 20. In the first direction y, the pad group 20 is located on a side of the wire-entry end 13 away from the second section portion 12. One pad group 20 is correspondingly connected to at least one wire-entry end 13. The pad group 20 is configured to bind a COF, and when assembled into a display device, the main board transmits a control signal to the display panel through the COF. In an embodiment of the present application, the wire-entry end 13 is configured to connect the pads in the pad group 20, and the position of the pad is the source of the power supply signal, so that the power supply signal is supplied to the power structure 10. In FIG. 2, one pad group 20 is correspondingly connected to two wire-entry ends 13 for illustration. This arrangement not only facilitates the symmetrical design of the wire-entry ends 13 and uniform the difference in the voltage drop of the power supply signal on the power supply structure 10, but also avoids the excessive number of pads connected to the wire-entry ends 13 to affect the transmission of other functional signals.

In some embodiments, n≤10. It can be understood that the number of n is related to the number of bound COFs. The COFs need to be connected to the main board through interfaces. The greater n is, the greater the number of bound COFs is, and thus the greater the number of connection interfaces is. In an embodiment of the application, it is set that 2≤n≤10, and the display panel can be driven by setting a plurality of groups of COFs, thus satisfying the requirement of driving capability and avoiding the excessive number of interfaces to increase the assembly difficulty.

In some embodiments, the display panel includes n−1 first dummy lines X1 extending in a first direction y, and two pad groups 20 adjacent in a second direction x are symmetrical with respect to the first dummy lines X1. The n−1 first dummy lines X1 divide the bending region Z into n sub-regions, one sub-region corresponds to one pad group 20, and m connection portions 14 are provided in one sub-region, where m is an integer, and m≥3.

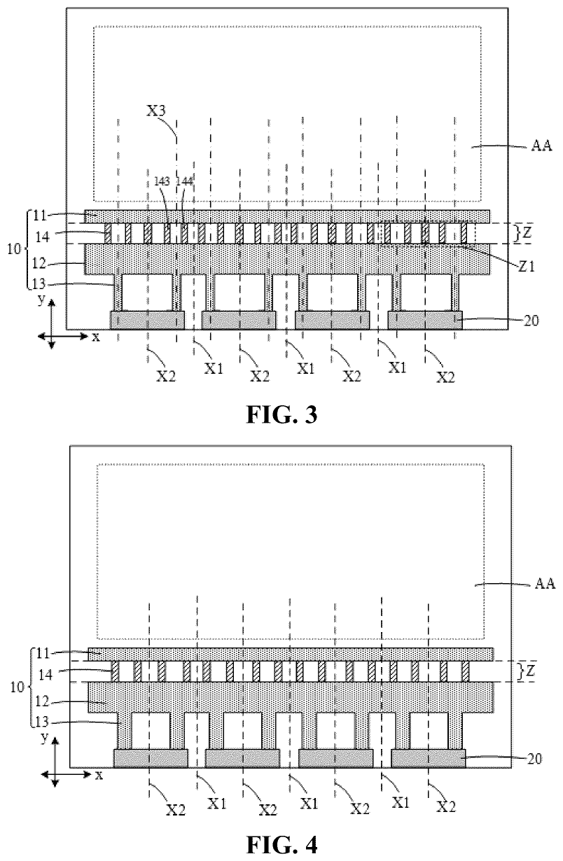

FIG. 3 is a schematic diagram of a display panel provided by another embodiment of the present application, and FIG. 3 takes n=4 and m=5 as examples. As shown in FIG. 3, the display panel includes three first dummy lines X1, and two pad groups 20 adjacent in the second direction x are symmetrical with respect to the first dummy lines X1. The three first dummy lines X1 divide the bending region Z into four sub-regions Z1, one sub-region Z1 corresponds to one pad group 20, and five connection portions 14 are provided in each sub-region Z1. In an embodiment of the present application, a sub-region Z1 basically corresponds to a current flow region where the wire-entry end 13 connected to a pad group 20 transmits the power supply signal. A plurality of connection portions 14 are provided in each sub-region Z1 so that the voltage drop when the power supply signal is transmitted from the second section 12 to the first section 11 can be relatively uniform, and current concentration is avoided, which is beneficial to uniform the voltage drop of the first section 11 in the second direction x, thereby ameliorating the problem of localized brightness of the side of the display area AA close to the side of the power supply structure 10 and improving display uniformity.

In some embodiments, as shown in FIG. 3, the display panel includes a second dummy line X2 extending in a first direction y. One pad group 20 corresponds to two wire-entry ends 13, and the two wire-entry ends 13 corresponding to one pad group 20 are symmetrical with respect to the second dummy line X2. Here, m (m=5 in FIG. 3) connection portions 14 in the sub-region Z1 are symmetrical with respect to the second dummy line X2. In this embodiment, one pad group 20 is provided to correspond to two wire-entry ends 13, and the two wire-entry ends 13 are symmetrical with respect to the second dummy line X2, and the plurality of connection portions 14 in the sub-region Z1 are also symmetrical with respect to the second dummy line X2. With this arrangement, the wire-entries can be dispersed and relatively uniform in the second direction x at both the wire-entry position of the power supply signal to the second section 12 and the wire-entry position of the power supply signal to the first section 11, and the voltage drop of the power supply signal can be uniform, thereby ameliorating the problem of localized brightness of the side of the display area AA close to the power supply structure 10 and improving display uniformity.

In another embodiment, FIG. 4 is a schematic diagram of a display panel provided by yet another embodiment of the present application, and FIG. 4 takes n=4 and m=4 as examples. As shown in FIG. 4, one pad group 20 corresponds to two wire-entry ends 13, and the two wire-entry ends 13 corresponding to one pad group 20 are symmetrical with respect to the second dummy line X2. There are four connection portions 14 in one sub-region Z1, and the four connection portions 14 are symmetrical with respect to the second dummy line X2. In an embodiment of the present application, a sub-region Z1 includes m connection portions 14, where m may be an odd number or an even number.

In some embodiments, one sub-region Z1 includes m connection portions 14, m is an odd number, and the (m+1)/2 ones of the m connection portions 14 in the sub-region overlap with the second dummy line. Taking FIG. 3 as an example, five connection portions 14 are provided in one sub-region Z1, and the third connection portion 14 arranged in the second direction x overlaps with the second dummy line X2. With this arrangement, the wire-entries can be dispersed and relatively uniform in the second direction x at the wire-entry position of the power supply signal to the first section 11, and the voltage drop of the power supply signal can be uniform, thereby ameliorating the problem of localized brightness of the side of the display area AA close to the power supply structure 10 and improving display uniformity.

In some embodiments, the display panel includes a second dummy line X2 extending in the first direction y, and two wire-entry ends 13 corresponding to one pad group 20 are symmetrical with respect to the second dummy line X2. The m connection portions 14 in the sub-region Z1 include a first connection portion and a second connection portion. In the second direction x, the distance from the first connection portion to the second dummy line X2 is less than the distance from the second connection portion to the second dummy line X2. In the second direction x, the width of the first connection portion is greater than the width of the second connection portion.

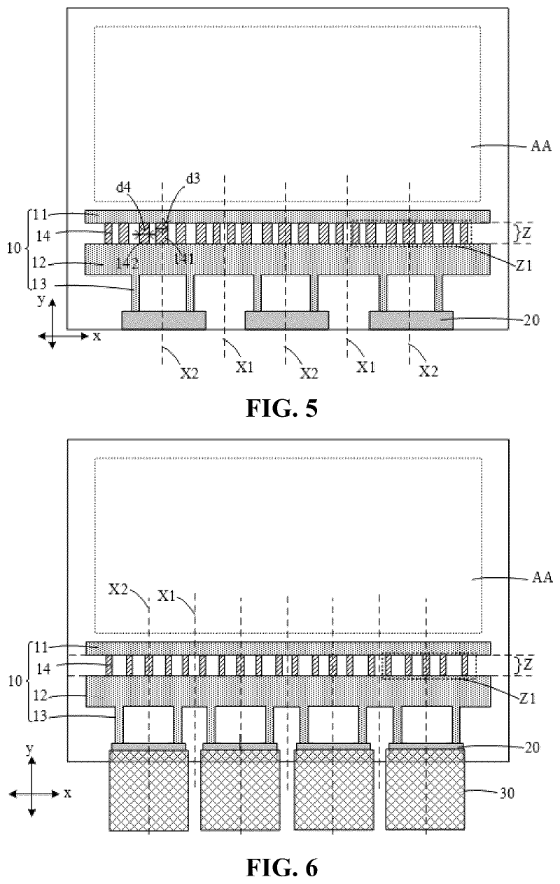

Take n=3 and m=7 as an example. FIG. 5 is a schematic diagram of a display panel provided by yet another embodiment of the present application. As shown in FIG. 5, the display panel includes a first dummy line X1 and a second dummy line X2. Two pad groups 20 adjacent in the second direction x are symmetrical with respect to the first dummy line X1 that divides the bending region Z into a plurality of sub-regions Z1. Two wire-entry ends 13 corresponding to one pad group 20 are symmetrical with respect to the second dummy line X2. The seven connection portions 14 in the sub-region Z1 include a first connection portion 141 and a second connection portion 142. In the second direction x, the distance from the first connection portion 141 to the second dummy line X2 is less than the distance from the second connection portion 142 to the second dummy line X2. In the second direction x, the width of the first connection portion 141 is d3, and the width of the second connection portion 142 is d4, and the width d3 of the first connection portion 141 is greater than the width d4 of the second connection portion 142. As can be seen from FIG. 5, in the second direction x, the distance from the first connection portion 141 to the wire-entry end 13 is less than the distance from the second connection portion 142 to the wire-entry end 13. By providing the width of the first connection portion 141 to be greater and the width of the second connection portion 142 to be less, the difference in the voltage drop at the position of the two connection portions with respect to the voltage drop at the position of the wire-entry end 13 can be less, and the uniformity of the voltage drop at each position of the first section 11 in the second direction x can be improved, thereby ameliorating the problem of the localized brightness of the side of the display area AA close to the power supply structure 10, and improving the display uniformity.

In some embodiments, in the second direction x, the width of the first connection portion 141 is d3 and the width of the second connection portion 142 is d4, where 1<d3:d4≤4. Optionally, both the width of the first connection portion 141 and the width of the second connection portion 142 are not less than 300 μm. In an embodiment of the present application, the ratio between d3 and d4 satisfies a certain range, so that the difference in the voltage drop at the positions of the two connection portions with respect to the voltage drop at the positions of the wire-entry end 13 is smaller, and the uniformity of the voltage drop at each position of the first section 11 in the second direction x can be improved.

In some embodiments, as shown in FIG. 5, in the second direction x, the width of m connection portions 14 in the sub-region Z1 in the second direction x first increases and then decreases. By regularly designing the width of the connection portion 14 according to the difference in the distance from the connection portions 14 to the second dummy line X2 in the second direction x, the difference in the voltage drop of each connection portion 14 at the position of the power supply signal can be reduced, and the uniformity of the voltage drop at the positions of the first section 11 in the second direction x can be improved. The problem of localized brightness of the side of the display area AA close to the power supply structure 10 can be ameliorated, and the display uniformity can be improved.

In some embodiments, as shown in FIG. 3, the display panel includes a third dummy line X3 extending in the first direction y, and the wire-entry ends 13 are symmetrical with respect to the third dummy line X3. The m connection portions 14 in the sub-region include a third connection portion 143 and a fourth connection portion 144 that are adjacent to each other. The third dummy line X3 is located between the third connection portion 143 and the fourth connection portion 144, and the third connection portion 143 and the fourth connection portion 144 are symmetrical with respect to the third dummy line X3. This arrangement makes the difference in the voltage drop of the power supply signal transmitted at the positions of the third connection portion 143 and the fourth connection portion 144 small, which is beneficial to ameliorating the problem of localized brightness of the side of the display area AA close to the power supply structure 10, and improving display uniformity.

In some embodiments, FIG. 6 is a schematic diagram of a display panel provided by yet another embodiment of the present application. As shown in FIG. 6, the display panel further includes a COF 30, and one pad group 20 is correspondingly bound to one COF 30. The main board transmits control signals to the display panel through the COF 30 when assembling the display device. The embodiment of the present application provides at least two pad groups 20 and at least two COFs 30, which can meet the driving requirements of medium-sized display panels in application.

As shown in FIG. 6, the display panel includes a second dummy line X2 extending in the first direction y, and two wire-entry ends 13 corresponding to one pad group 20 are symmetrical with respect to the second dummy line X2. Here, the COFs 30 are symmetrical with respect to the second dummy line X2. The two wire-entry ends 13 are provided symmetrically with respect to the second dummy line X2, so that the wire-entries are distributed and relatively uniform in the second direction x at the wire-entry position of the power supply signal to the second section 12, and the voltage drop of the power supply signal can be uniform. Further, by providing the COF 30 to be symmetrical with respect to the second dummy line X2, the space in the region where the plurality of pad groups 20 are located can be reasonably utilized, and the corresponding bonding yield between the COF 30 and the pad groups 20 can be ensured.

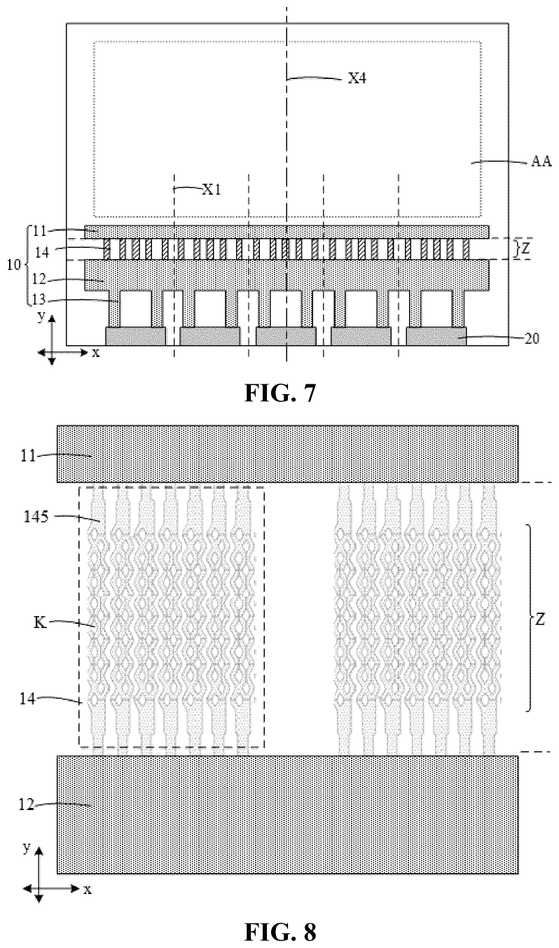

In some embodiments, FIG. 7 is a schematic diagram of a display panel provided by another embodiment of the present application. As shown in FIG. 7, the display area AA has a first symmetry axis X4 extending in the first direction y. The power supply structure 10 includes N wire-entry ends 13 arranged in the second direction x, where N is an integer. The N wire-entry ends 13 are symmetrical with respect to the first symmetry axis X4, where N may be an odd or even number. When p wire-entry ends 13 are provided correspondingly to one pad group 20, n=n*p, where n is the number of pad groups 20 in the display panel, and p is a positive integer. In an embodiment of the present application, the N wire-entry ends 13 are symmetrical with respect to the first symmetry axis X4 of the display area AA, so that the difference in voltage drop between the wire-entry ends 13 on the left and right sides of the first symmetry axis X4 can be small when the wire-entries are introduced to the second section 12, and the uniformity of the voltage drop at each position on the second section 12 can be improved, which is beneficial to ameliorating the problem of localized brightness of the side of the display area AA close to the power supply structure 10, and the display uniformity can be improved.

In some embodiments, FIG. 8 is a partial schematic diagram of a display panel provided by yet another embodiment of the present application, and FIG. 8 schematically illustrates a partial position near the bending region Z. As shown in FIG. 8, the connection portion 14 is connected between the first section 11 and the second section 12. The connection portion 14 includes a plurality of connection lines 145 extending in the first direction y, and the plurality of connection lines 145 in one connection portion 14 are arranged at equal intervals in the second direction x. In this embodiment, one connection portion 14 includes a plurality of connection lines 145. A plurality of signal output paths can be formed at the position of the connection portion 14, and the plurality of connection lines 145 are arranged at intervals to avoid failure in fabrication of large pieces of metal at a local position. Bending stress can be released when the bending area Z is bent, so as to avoid disconnection of the connection portion 14, thereby improving the performance reliability of the display panel.

Further, as shown in FIG. 8, the connection line 145 includes a plurality of hollows K, and the design of the hollows K further releases stress caused by bending and avoids disconnection. FIG. 8 shows that the connection line 145 is a diamond-twist-shaped trace, and the connection line 145 provided by an embodiment of the present application may also be a curve, a serpentine line, a single circular hole trace, a double circular hole staggered trace, or the like.

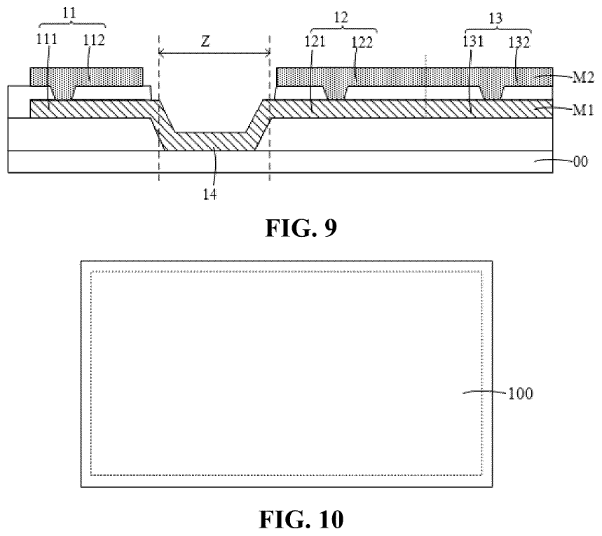

In some embodiments, FIG. 9 is a schematic cross-sectional view at line A-A′ position in FIG. 2. As shown in FIG. 9, the display panel includes a first metal layer M1 and a second metal layer M2 located on a side of the substrate 00. The first section 11 includes a first sub-portion 111 located on the first metal layer M1 and a second sub-portion 112 located on the second metal layer M2, and the first sub-portion 111 and the second sub-portion 112 are connected by a via penetrating the insulating layer. The second section 12 includes a third sub-portion 121 located in the first metal layer M1 and a fourth sub-portion 122 located in the second metal layer M2, and the third sub-portion 121 and the fourth sub-portion 122 are connected by a via hole penetrating the insulating layer. The wire-entry end 13 includes a fifth sub-portion 131 located in the first metal layer M1 and a sixth sub-portion 132 located in the second metal layer M2. The fifth sub-portion 131 and the sixth sub-portion 132 are connected to each other by a via hole penetrating the insulating layer. The connection portion 14 is located in one of the first metal layer M1 and the second metal layer M2. FIG. 9 illustrates that the connection portion 14 is located in the first metal layer M1. In this embodiment, the first section 11, the second section 12, and the wire-entry end 13 are provided to each include two sub-portions located on two metal layers, so that the resistance of the first section 11, the second section 12, and the wire-entry end 13 can be reduced, and the voltage drop of the power supply signal transmitted by the power supply structure 10 can be reduced. By providing the connection portion 14 on one metal layer, the bending resistance of the connection portion 14 can be improved, and the risk of disconnection of the connection portion 14 when the bending region Z is bent can be reduced.

Optionally, the first metal layer M1 and the second metal layer M2 include the same material, such as metallic titanium and/or metallic aluminum.

Based on the same inventive concept, embodiments of the present application further provide a display device. FIG. 10 is a schematic diagram of a display device provided by an embodiment of the present application. As shown in FIG. 10, the display device includes the display panel 100 provided by any one of the embodiments of the present application. The structure of the display panel 100 has been described in the above-described embodiments, and will not be described herein. The display device provided in the embodiments of the present application may be, for example, an in-vehicle display device or an electronic device such as a television or a computer.

The above description are merely preferred embodiments of the present application and not intended to limit the present application, and any modifications, equivalents, improvements, etc. made within the spirit and principles of the present application should be included within the scope of protection of the present application.

Finally, it should be noted that the above embodiments are merely used to illustrate the technical solution of the present application, and are not intended to limit it. Although the present application has been described in detail with reference to the above-described embodiments, it should be understood by those skilled in the art that the technical solutions described in the above-described embodiments can be modified, or some or all of the technical features thereof can be equivalently replaced. However, these modifications or substitutions do not cause the essence of the corresponding technical solutions to deviate from the scope of the technical solutions of each embodiment of the present application.

What is claimed is:

1. A display panel, comprising a display area and a non-display area, wherein
the display panel comprises a substrate and a power supply structure located on a side of the substrate, the power supply structure being located in the non-display area and located on a side of the display area in a first direction;
the power supply structure comprises a first section, a second section, a wire-entry end, and a connection portion, the first section, the connection portion, the second section, and the wire-entry end being sequentially arranged away from the display area in the first direction;
the connection portion extends in the first direction, the first section and the second section extend in a second direction intersecting with the first direction, the connection portion is connected to the first section and the second section, and the wire-entry end is connected to the second section; and
the substrate is provided with a bending region located between the first section and the second section in the first direction, and at least part of the connection portion is located in the bending region.

2. The display panel of claim 1, wherein in the first direction, a width of the second section is greater than a width of the first section.

3. The display panel of claim 2, wherein in the first direction, the width of the first section is d1 and the width of the second section is d2, where 0.25≤d1:d2≤0.5.

4. The display panel of claim 1, wherein in the first direction, a width of the second section is d2, where d2≥500 μm.

5. The display panel of claim 1, wherein in the first direction, a distance from the first section to the display area is D, where 100 μm≤D≤500 μm.

6. The display panel of claim 1, wherein in the first direction, the connection portion and the wire-entry end are at least partially non-overlapping.

7. The display panel of claim 1, wherein the display panel comprises n pad groups, where n is an integer, and n≥2; and
each of the n pad groups comprises a plurality of pads arranged in the second direction, in the first direction, the n pad groups are located on a side of the wire-entry end away from the second section; one of the n pad groups is correspondingly connected to at least one of the wire-entry ends.

8. The display panel of claim 7, wherein the display panel comprises n−1 first dummy lines extending in the first direction, and two of the pad groups adjacent in the second direction are symmetrical with respect to one of the first dummy lines; and
the n−1 first dummy lines divide the bending region into n sub-regions, one of the n sub-regions corresponds to one of the pad groups, and m connection portions are provided in one of the sub-regions, where m is an integer, and m≥3.

9. The display panel of claim 8, wherein the display panel comprises a second dummy line extending in the first direction;
one of the pad groups corresponds to two of the wire-entry ends, and two of the wire-entry ends corresponding to one of the pad groups are symmetrical with respect to the second dummy line;
the m connection portions within the sub-region are symmetrical with respect to the second dummy line.

10. The display panel of claim 8, wherein the display panel comprises a second dummy line extending in the first direction, and two of the wire-entry ends corresponding to one of the pad groups are symmetrical with respect to the second dummy line;
(m+1)/2 ones of the m connection portions in the sub-region overlap with the second dummy line, where m is an odd number.

11. The display panel of claim 8, wherein the display panel comprises a second dummy line extending along the first direction, and two of the wire-entry ends corresponding to one of the pad groups are symmetrical with respect to the second dummy line;
the m connection portions in the sub-region comprise a first connection portion and a second connection portion; a distance from the first connection portion to the second dummy line in the second direction is less than a distance from the second connection portion to the second dummy line; and
in the second direction, a width of the first connection portion is greater than a width of the second connection portion.

12. The display panel of claim 11, wherein in the second direction, the width of the first connection portion is d3 and the width of the second connection portion is d4, where 1<d3:d4≤4.

13. The display panel of claim 8, wherein in the second direction, the width of the m connection portions in the sub-region in the second direction first increases and then decreases.

14. The display panel of claim 8, wherein the display panel comprises a third dummy line extending in the first direction, the wire-entry ends are symmetrical with respect to the third dummy line; and
the m connection portions within the sub-region comprise a third connection portion and a fourth connection portion that are adjacent to each other, the third dummy line being located between the third connection portion and the fourth connection portion, the third connection portion and the fourth connection portion being symmetrical with respect to the third dummy line.

15. The display panel of claim 7, wherein the display panel further includes a Chip-On-Flex (COF), and one of the pad groups is correspondingly bound to one of the COFs.

16. The display panel of claim 15, wherein the display panel comprises a second dummy line extending in the first direction, and two of the wire-entry ends corresponding to one of the pad groups are symmetrical with respect to the second dummy line; and
the COFs are symmetric with respect to the second dummy line.

17. The display panel according to claim 1, wherein the display region has a first symmetry axis extending in the first direction;
the power supply structure comprises N wire-entry ends arranged in the second direction, N being an integer; and
the N wire-entry ends are symmetrical with respect to the first symmetry axis.

18. The display panel of claim 1, wherein the connection portion comprises a plurality of connection lines extending in the first direction, and the plurality of connection lines in one of the connection portions are arranged at equal intervals in the second direction.

19. The display panel of claim 1, wherein the display panel comprises a first metal layer and a second metal layer located on a side of the substrate, the first section comprises a first sub-portion located on the first metal layer and a second sub-portion located on the second metal layer, the second section comprises a third sub-portion located on the first metal layer and a fourth sub-portion located on the second metal layer, and the wire-entry end comprises a fifth sub-portion located on the first metal layer and a sixth sub-portion located on the second metal layer; and
the connection portion is located in one of the first metal layer and the second metal layer.

20. A display device, comprising a display panel, comprising a display area and a non-display area, wherein
the display panel comprises a substrate and a power supply structure located on a side of the substrate, the power supply structure being located in the non-display area and located on a side of the display area in a first direction;
the power supply structure comprises a first section, a second section, a wire-entry end, and a connection portion, the first section, the connection portion, the second section, and the wire-entry end being sequentially arranged away from the display area in the first direction;
the connection portion extends in the first direction, the first section and the second section extend in a second direction intersecting with the first direction, the connection portion is connected to the first section and the second section, and the wire-entry end is connected to the second section; and
the substrate is provided with a bending region located between the first section and the second section in the first direction, and at least part of the connection portion is located in the bending region.
